(19) United States
(12) Patent Application Publication
(10) Pub. No.: US 2007/0264734 A1
(43) Pub. Date: Nov. 15, 2007

(54) Solid-state laser device and method for manufacturing wavelength conversion optical member

(76) Inventors: Masayuki Momiuchi, Tokyo-to (JP); Taizo Eno, Tokyo-to (JP); Yoshiaki Goto, Tokyo-to (JP)

Correspondence Address: NIELDS & LEMACK, 176 EAST MAIN STREET, SUITE 7, WESTBORO, MA, 01581, US

(21) Appl. No.: 11/880,269

(22) Filed: Jul. 20, 2007

Related U.S. Application Data
(62) Division of application No. 10/895,505, filed on Jul. 21, 2004.

(30) Foreign Application Priority Data
Aug. 4, 2003 (JP) JP2003-285993

(51) Int. Cl. H01L 33/00

(52) U.S. Cl. 438/26; 257/E33.067

(57) ABSTRACT

A solid-state laser device, comprising a wavelength conversion optical member, wherein the wavelength conversion optical member comprises a laser crystal and a wavelength conversion element cemented together, and a first dielectric reflection film poorly reflective to a fundamental wave and highly reflective to a wavelength conversion light is formed on a cemented surface.

This application is a divisional of U.S. Ser. No. 10/895,505 filed Jul. 21, 2004, the disclosure of which is incorporated herein by reference.

### BACKGROUND OF THE INVENTION

The present invention relates to a solid-state laser device, in particular, to a semiconductor laser device, and relates to a solid-state laser device for oscillating with two wavelengths by a resonator and for converting the wavelength in the resonator.

A diode pumped solid-state laser using an intracavity type SHG mode is known as a device to convert frequency of a laser beam from a semiconductor laser.

FIG. 7 represents a laser light source 1, which is a diode pumped solid-state laser of single wavelength oscillation.

In FIG. 7, reference numeral 2 denotes a light emitting unit, and 3 denotes an optical resonator. The light emitting unit 2 comprises an LD light emitter 4 and a condenser lens 5. Further, the optical resonator 3 comprises a laser crystal 8 with a dielectric reflection film 7 formed on it, a non-linear type optical medium (NLO) 9, and a concave mirror 12 with a dielectric reflection film 11 formed on it. A laser beam is pumped at the optical resonator 3, and it is outputted after being resonated and amplified. As the laser crystal 8, Nd:YVO₄ may be used. As the non-linear type optical medium 9, KTP (KTiOPO₄; titanyl potassium phosphate) may be used.

Detailed description is given below:

A laser light emitting means is used to emit a linearly polarized laser beam with a wavelength of 809 nm as an excitation light, and the LD light emitter 4, i.e. a semiconductor laser, is used. The LD light emitter 4 has the function as an excitation light generator, which generates an excitation light. The laser light emitting means is not limited to a semiconductor laser, and any type of laser light emitting means may be used so far as the laser light emitting means can generate a laser beam.

The laser crystal 8 performs amplification of light. As the laser crystal 8, Nd:YVO₄ with an oscillation line of 1064 nm may be used. Further, YAG (yttrium aluminum garnet) doped with Nd³⁺ ions, etc. is used. YAG has oscillation lines of 946 nm, 1064 nm, 1319 nm, etc. Also, Ti (sapphire) with oscillation line of 700-900 nm, etc. may be used.

On the side of the laser crystal 8 closer to the LD light emitter 4, a dielectric reflection film 7 is formed. The dielectric reflection film 7 is highly transmissive to a laser beam from the LD light emitter 4, and the dielectric reflection film 7 is highly reflective to an oscillation wave (fundamental wave) of the laser crystal 8. The dielectric reflection film 7 is also highly reflective to a wavelength conversion light, e.g. a secondary higher harmonic wave (SHG: second harmonic generation).

The concave mirror 12 is designed in such manner that it is oppositely positioned to the laser crystal 8. The side of the concave mirror 12 closer to the laser crystal 8 is fabricated to have a shape of concave spherical mirror with an appropriate radius, and the dielectric reflection film 11 is formed on it. The dielectric reflection film 11 is highly reflective to an oscillation wave (fundamental wave) of the laser crystal 8, and the dielectric reflection film 11 is highly transmissive to SHG (second harmonic generation).

As described above, when the dielectric reflection film 7 of the laser crystal 8 is combined with the dielectric reflection film 11 of the concave mirror 12 and when a laser beam from the LD light emitter 4 is pumped to the laser crystal 8 via the condenser lens 5, the light runs reciprocally between the dielectric reflection film 7 of the laser crystal 8 and the dielectric reflection film 11 of the concave mirror 12. Thus, the light can be confined for long time, and the light can be resonated and amplified.

The non-linear type optical medium 9 is placed in the optical resonator, which comprises the dielectric reflection film 7 of the laser crystal 8 and the concave mirror 12. When a laser beam with a specific frequency enters the non-linear optical medium 9, a secondary higher harmonic wave (SHG) is generated, which converts the optical frequency by two times. The generation of the secondary higher harmonic wave is called “second harmonic generation”. Therefore, a laser beam with wavelength of 532 nm is projected from the laser light source 1.

In the laser light source 1 as described above, the non-linear type optical medium (hereinafter referred as “wavelength conversion element”) 9 is placed in the optical resonator, which comprises the laser crystal 8 and the concave mirror 12, and it is called an intracavity type SHG. Conversion output is proportional to a square of the fundamental wave output, and it provides the effect that high optical intensity in the optical resonator can be directly utilized.

In the solid-state laser device shown in FIG. 7, the secondary higher harmonic wave (hereinafter referred as “wavelength conversion light”) generated at the wavelength conversion element 9 is projected from an end surface of the wavelength conversion element 9 closer to the concave mirror 12 and from an end surface closer to the laser crystal 8. The wavelength conversion light projected from the end surface closer to the concave mirror 12 is projected after passing through the dielectric reflection film 11 and the concave mirror 12. The wavelength conversion light projected from the end surface closer to the laser crystal 8 passes through the laser crystal 8 and is reflected by the dielectric reflection film 7. Then, the wavelength conversion light is projected after passing through the wavelength conversion element 9, the dielectric reflection film 11 and the concave mirror 12.

The laser crystal 8 has an action as a wave plate. When the wavelength conversion light passes through the laser crystal 8, a plane of polarization is rotated and the light is turned to an elliptically polarized light. The wavelength conversion light projected from the concave mirror 12 is turned to a laser beam including the elliptically polarized component.

In an operation such as surveying operation, a linearly polarized laser beam is required. In the laser light source 1 as described above, an optical element such as a polarizing plate for converting the projected laser beam to a linearly polarized light is used. For this reason, more complicated optical system is needed, and this leads to higher cost and to the difficulty to achieve compact design.

### SUMMARY OF THE INVENTION

It is an object of the present invention to provide a solid-state laser device, which has a simple arrangement and by which it is possible to achieve reduction of cost and compact design and to obtain a linearly polarized light.

To attain the above object, the present invention provides a solid-state laser device, which comprises a wavelength conversion optical member, wherein the wavelength conversion optical member comprises a laser crystal and a wavelength conversion element cemented together, and a first dielectric reflection film poorly reflective to a fundamental wave and highly reflective to a wavelength conversion light is formed on a cemented surface. Also, the present invention provides the solid-state laser device as described above, wherein the laser crystal and the wavelength conversion element are optically not in contact with each other. Further, the present invention provides the solid-state laser device as described above, wherein the optically non-contact condition can be achieved by forming a gap between the laser crystal and the wavelength conversion element. Also, the present invention provides the solid-state laser device as described above, wherein the optically non-contact condition can be achieved by forming a transparent sheet between the laser crystal and the wavelength conversion element. Further, the present invention provides the solid-state laser device as described above, wherein a gap is formed by placing a spacer with a hole between the laser crystal and the wavelength conversion element. Also, the present invention provides the solid-state laser device as described above, wherein the spacer is a plated film. Further, the present invention provides the solid-state laser device as described above, wherein the first dielectric reflection film comprising a gap formed between a dielectric film and a dielectric film provided on two cemented surfaces of the laser crystal and the wavelength conversion element, one of the dielectric films is poorly reflective to the fundamental wave and highly reflective to a wavelength conversion light, and the other of the dielectric films is poorly reflective to the fundamental wave. Also, the present invention provides the solid-state laser device as described above, wherein the wavelength conversion optical member is disposed between dielectric reflection films which are highly reflective to the fundamental wave, and the dielectric reflection films and the wavelength conversion optical member make up together an optical resonator. Further, the present invention provides the solid-state laser device as described above, wherein the dielectric reflection film is formed on at least one of and surfaces of the wavelength conversion optical member. Also, the present invention provides the solid-state laser device as described above, wherein a metal layer is formed on side surfaces of the wavelength conversion optical member.

The present invention provides a method for manufacturing a wavelength conversion optical member in a solid-state laser device, the method comprising the step of forming a dielectric film on a cemented surface of a laser crystal plate, the step of forming a dielectric film on a cemented surface of a wavelength conversion element plate, and the step of cementing the laser crystal plate with the wavelength conversion element plate by arranging a spacer film with a hole in an optical path portion, wherein one of the dielectric films is poorly reflective to a fundamental wave and highly reflective to a wavelength conversion light, and the other of the dielectric films is poorly reflective to the fundamental wave. Also, the present invention provides the method for manufacturing a wavelength conversion optical member as described above, further comprising the step of cementing the laser crystal plate with the wavelength conversion element plate via the spacer film which has a plurality of holes, and the step of dividing the laser crystal plate, the wavelength conversion element plate and the spacer film cemented together so as to have each of holes in each individual section.

The solid-state laser device according to the present invention comprises a wavelength conversion optical member, and the wavelength conversion optical member comprises a laser crystal and a wavelength conversion element cemented together. On the cemented surface, a first dielectric reflection film is formed, which is poorly reflective to a fundamental wave and is highly reflective to a wavelength conversion light. Therefore, the wavelength conversion light with its wavelength converted by the wavelength conversion element does not pass through the laser crystal, and the wavelength conversion light is reflected by the first dielectric reflection film and is projected as an output light. Thus, the plane of polarization of the output light does not change. The laser crystal and the wavelength conversion element are cemented together. As a result, it is possible to achieve compact design, and working efficiency is improved as a single optical member.

According to the present invention, the wavelength conversion optical member is placed between dielectric reflection films, which are highly reflective to the fundamental wave. Also, the dielectric reflection film is formed on at least one of end surfaces of the wavelength conversion optical member, and an optical resonator is constructed. As a result, there is no need to provide individual reflection mirrors. This contributes to compact design and simple arrangement of the resonator.

Also, the present invention provides a method for manufacturing a wavelength conversion optical member in a solid-state laser device, the method comprising the steps of forming a dielectric film on a cemented surface of a laser crystal plate, of forming a dielectric film on a cemented surface of a wavelength conversion element plate, and of cementing the laser crystal plate with the wavelength conversion element plate by arranging a spacer film with a hole in an optical path portion. Also, the spacer film comprises a plurality of holes, and the method further comprises the step of dividing the spacer film so that each of the holes is contained in each of the divided sections after the laser crystal plate and the wavelength conversion element plate are cemented together. As a result, it is possible to manufacture a plurality of wavelength conversion optical members at the same time, and stable quality can be assured.

### BRIEF DESCRIPTION OF THE DRAWINGS

FIG. 1 is a schematical drawing of an essential portion of a first embodiment of the present invention;

FIG. 2 is a schematical drawing of an essential portion of a second embodiment of the present invention;

FIG. 3 is a schematical drawing of an essential portion of a third embodiment of the present invention;

FIG. 4 is a schematical drawing of an essential portion of a fourth embodiment of the present invention;

FIG. 5 shows a manufacturing method according to the present invention. FIG. 5 (A) is an illustrative drawing of a process, and FIG. 5 (B) is an illustrative drawing of a spacer film used in the process;

FIG. 6 is an illustrative drawing of another type of a spacer film used in the manufacturing method; and

FIG. 7 is a schematical block diagram of a conventional example.

### DETAILED DESCRIPTION OF THE PREFERRED EMBODIMENTS

Description will be given below on embodiments of the present invention referring to the drawings.

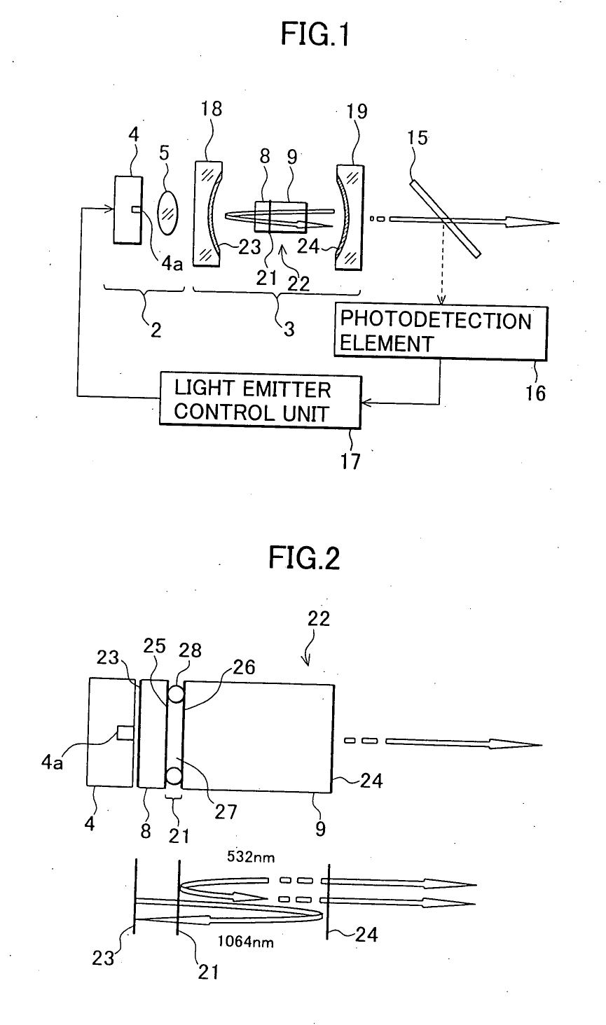

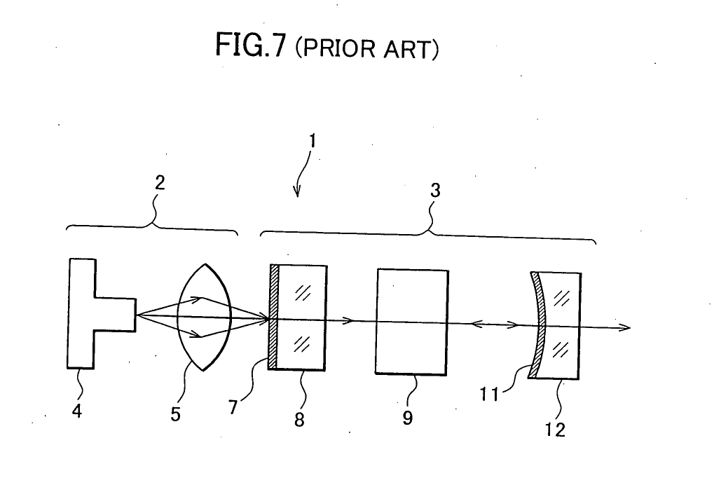

FIG. 1 represents a first embodiment of the present invention. In FIG. 1, the equivalent component as shown in FIG. 7 is referred by the same symbol.

An optical resonator 3 is oppositely positioned to a light emitting unit 2, and a half-mirror 15 is disposed on a laser beam exit side of the optical resonator 3. The half-mirror 15 reflects a part of an emitted laser beam, and a photodetection element 16 is arranged at a position opposite to the half-mirror 15. The photodetection element 16 receives a part of the laser beam reflected by the half-mirror 15 and inputs an output light detection signal to a light emitter control unit 17. The light emitter control unit 17 controls the light emitting unit 2 based on the output light detection signal so that a predetermined output, e.g. an excitation light with a constant output, is emitted from the light emitting unit 2.

The light emitting unit 2 comprises an LD light emitter 4 and a condenser lens 5 arranged at a position opposite to the LD light emitter 4. The LD light emitter 4 has a semiconductor laser light emitting element 4a.

The optical resonator 3 has reflection mirrors 18 and 19 oppositely positioned to each other, and a laser crystal 8 and a wavelength conversion element 9 are disposed between the reflection mirrors 18 and 19. The laser crystal 8 and the wavelength conversion element 9 are connected with each other via a first dielectric reflection film 21 so that the two crystal axes run at an angle suitable for the oscillated wavelength. The laser crystal 8 and the wavelength conversion element 9 make up together a wavelength conversion optical member 22. The first dielectric reflection film 21 is coated by evaporation, sputtering, etc.

Each of the reflection mirrors 18 and 19 has a concave surface facing to each other. A second dielectric reflection film 23 is formed on the concave surface of the reflection mirror 18, and a third dielectric reflection film 24 is formed on the concave surface of the reflection mirror 19. A reflection preventive film (AR coat) is provided respectively on a non-cemented end surface of the laser crystal 8 and on a non-cemented end surface of the wavelength conversion element 9. A metal layer is formed by means such as metal plating on four surfaces running in parallel to an optical path of the wavelength conversion optical members 22 (the laser crystal 8 and the wavelength conversion element 9) and also on two side surfaces running perpendicular to the optical path (except optical path portion). The second dielectric reflection film 23 and the third dielectric reflection film 24 are coated by evaporation, sputtering, etc.

In the laser crystal 8 and the wavelength conversion element 9, element temperature is increased due to light absorption associated with wavelength conversion, etc. Because of poor thermal transfer, temperature distribution is not even, and this causes the decrease of optical characteristics and wavelength conversion efficiency.

The metal layer is effective for increasing heat radiation effect and for keeping even distribution of temperature. If metal such as In, Cu, Au, etc. with superior thermal conductivity is attached on the side surface of the crystal by means such as vacuum evaporation, plating, fusion, etc. to form a metal layer, it is possible to promote heat migration and to have even temperature distribution. Further, soldering can be performed when the element is solidified, and this contributes not only to the improvement of the thermal characteristics but also to the promotion of working efficiency and reliability.

The second dielectric reflection film 23 has such characteristics as being poorly reflective (e.g. reflectivity R<5%) to an excitation light (e.g. 809 nm), and being highly reflective (e.g. reflectivity R>99.8%) to a fundamental wave (e.g. 1064 nm).

The second dielectric reflection film 23 may have such characteristics as being poorly reflective (e.g. reflectivity R<5%) to an excitation light (e.g. 809 nm), and being non-reflective (e.g. reflectivity R<0.1%) to a fundamental wave (e.g. 1064 nm).

The first dielectric reflection film 21 has such characteristics as being non-reflective (e.g. R<0.1%) to a fundamental wave, and being highly reflective (R>95%) to a secondary higher harmonic wave light (wavelength conversion light; e.g. 532-nm).

The third dielectric reflection film 24 has such characteristics as being non-reflective (e.g. reflectivity R<0.1%) to a fundamental wave (e.g. 1064 nm), and being poorly reflective (e.g. reflectivity R<5%) to a wavelength conversion light (e.g. 532 nm).

The third dielectric reflection film 24 may have such characteristics as being highly reflective (e.g. reflectivity R>99.5%) to a fundamental wave (e.g. 1064 nm), and being poorly reflective (e.g. reflectivity R<5%) to a wavelength conversion light (e.g. 532 nm).

A linearly polarized excitation light emitted from the light emitting element 4a is converted to a fundamental wave by the laser crystal 8, and it is then pumped and amplified between the second dielectric reflection film 23 and the third dielectric reflection film 24. From the fundamental wave, a wavelength conversion light is generated by the wavelength conversion element 9. A part of the wavelength conversion light is projected via the reflection mirror 19 directly from the end surface of the wavelength conversion element 9 closer to the reflection mirror 19. The wavelength conversion light projected from the side of the wavelength conversion element 9 closer to the reflection mirror 18 is reflected by the first dielectric reflection film 21, and it is projected via the reflection mirror 19 from the end surface of the wavelength conversion element 9 closer to the reflection mirror 19. The wavelength conversion light generated at the wavelength conversion element 9 does not pass through the laser crystal 8, and the laser beam projected from the reflection mirror 19 maintains the linearly polarized light without being affected by the wave plate action of the laser crystal 8.

The reflection preventive films formed on the laser crystal 8 and the wavelength conversion element 9 suppress reflection of the laser beam on the non-cemented surfaces of the laser crystal 8 and the wavelength conversion element 9 and reduce the loss of light. The second dielectric reflection film 23 and the third dielectric reflection film 24 designed as concave surfaces converge the laser beam projecting the fundamental wave to the wavelength conversion element 9 and increase energy density, thereby increasing wavelength conversion efficiency in the wavelength conversion element 9.

When the solid-state laser device is operated under high output condition, the wavelength conversion optical member 22 may be deteriorated as time elapses. In the above embodiment, however, the wavelength conversion optical member 22 is constructed by cementing the laser crystal 8 and the wavelength conversion element 9 with each other via the first dielectric reflection film 21. Thus, when the output is decreased, for instance, quick and easy action can be taken by replacing the integrated wavelength conversion optical member 22. Also, the wavelength conversion optical member 22 comprises the first dielectric reflection film 21 simply formed on the cemented surface, and it can be produced at lower cost.

Now, description will be given on a variation of the first embodiment.

As described above, the dielectric reflection film 21 is formed between the laser crystal 8 and the wavelength conversion element 9. It is difficult and involves high cost to form the dielectric reflection film 21 so that the dielectric reflection film 21 has such characteristics as being non-reflective to the fundamental wave and as being highly reflective to the wavelength conversion light for both of the laser crystal 8 and the wavelength conversion element 9. Therefore, in the variation described below, the laser crystal 8 and the wavelength conversion element 9 are physically connected and optically non-cemented. On one of the cemented surfaces of the laser crystal 8 and the wavelength conversion element 9, a dielectric film is formed, which is non-reflective (R<0.1%) to the fundamental wave and highly reflective to the wavelength conversion light (e.g. R>95%), and a dielectric film non-reflective (R<0.1%) to the fundamental wave is formed on the other of the cemented surfaces. The first dielectric reflection film 21 is formed by two dielectric films and a gap which is formed between two dielectric films. In the two dielectric films, consideration should be given only to film characteristics with respect to the gap, and film can be formed easily. Here, the gap is air or a transparent sheet. There is no need to give consideration on optical contact between the laser crystal 8 and the wavelength conversion element 9, and this facilitates easy assembling. The dielectric films are coated by evaporation, sputtering, etc.

To achieve optical non-cementing, there is a method to form a gap for at least a part of the cemented surface where the laser beam passes through or a method to provide a transparent sheet, e.g. a transparent sheet made of glass, which gives no optical influence on the cemented surface.

The gap and the thickness of the sheet should be set to about 0.002 mm or more, or more preferably to about 0.002-0.5 mm by taking the conversion wavelength into account.

FIG. 2 shows a second embodiment of the present invention. In FIG. 2, the same component as shown in FIG. 1 is referred by the same symbol. In the figure, reference numerals 25 and 26 represent dielectric films formed on the cemented surface of the laser crystal 8 and on the cemented surface of the wavelength conversion element 9 respectively. The numeral 27 denotes a gap, and 28 represents a spacer for forming the gap. The dielectric films 25 and 26 are coated by vacuum evaporation, sputtering, etc.

In the second embodiment, the reflection mirrors 18 and 19 shown in the first embodiment are not provided. The second dielectric reflection film 23 is formed on the non-cemented end surface of the laser crystal 8, and the third dielectric reflection film 24 is formed on the non-cemented end surface of the wavelength conversion element 9.

The spacer 28 for forming the gap 27 is provided on at least one of the cemented surfaces of the laser crystal 8 and the wavelength conversion element 9. The spacer 28 is a plated film formed by curing an optical path portion, or the spacer 28 is a joined metal used when the laser crystal 8 and the wavelength conversion element 9 are cemented together. As the spacer using the joined metal, it is designed, for instance, in such manner that the solid-state laser crystal 8 and the wavelength conversion element 9 are cemented together in the surrounding region except the optical path by using a metal with low melting point, e.g. indium, and the joined metal is used as the spacer 28. Or, a metal foil, e.g. aluminum foil, stainless steel foil, etc., formed by gouging out the optical path portion, is provided between the laser crystal 8 and the wavelength conversion element 9. When a film such as a plated film is formed and it is used as the spacer 28, a peelable material may be coated on the optical path portion, and the plated film is formed on the entire cemented joint surface, and the optical path portion may be peeled off later.

Next, description will be given on film formation of the first dielectric reflection film 21, the second dielectric reflection film 23, and the third dielectric reflection film 24.

In case a dielectric reflection film with reflectivity as desired is to be formed, a material with high refractive index, e.g. Ta₂O₅ (tantalum pentoxide) or ZrO₂ (zirconium dioxide), and a material with low refractive index, e.g. SiO₂ (silicon dioxide), are laminated alternately in several to several tens of layers in thickness of λ/4 to obtain the desired reflectivity (λ represents a wavelength of a laser beam).

The laser crystal 8 and the wavelength conversion element 9 are cemented together via the first dielectric reflection film 21, and the second dielectric reflection film 23 and the third dielectric reflection film 24 are formed on the laser crystal 8 and the wavelength conversion element 9 respectively. Thus, the optical resonator 3 can be turned to a form of a chip. The optical resonator 3 in compact size and with high efficiency as well as with smaller extinction ratio can be obtained. Further, a linearly polarized wavelength conversion light can be obtained by using a semiconductor laser in the light emitting unit 2 because the optical resonator 3 does not exert influence on the plane of polarization.

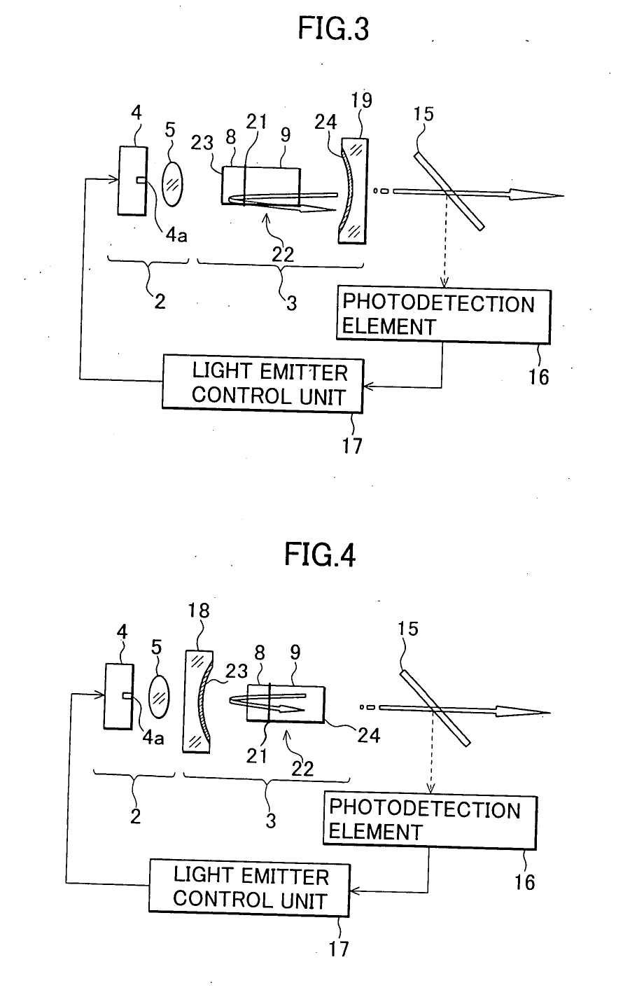

FIG. 3 represents a third embodiment of the invention, and FIG. 4 shows a fourth embodiment. The equivalent component as shown in FIG. 1 is referred by the same symbol.

In the third embodiment, the reflection mirror 18 as shown in the first embodiment is not used, and the second dielectric reflection film 23 is formed on the non-cemented end surface of the laser crystal 8. In the fourth embodiment, the reflection mirror 19 shown in the first embodiment is not used, and the third dielectric reflection film 24 is formed on the non-cemented end surface of the wavelength conversion element 9. Each of these components exerts the equivalent action as in the first embodiment, and the details are not given here.

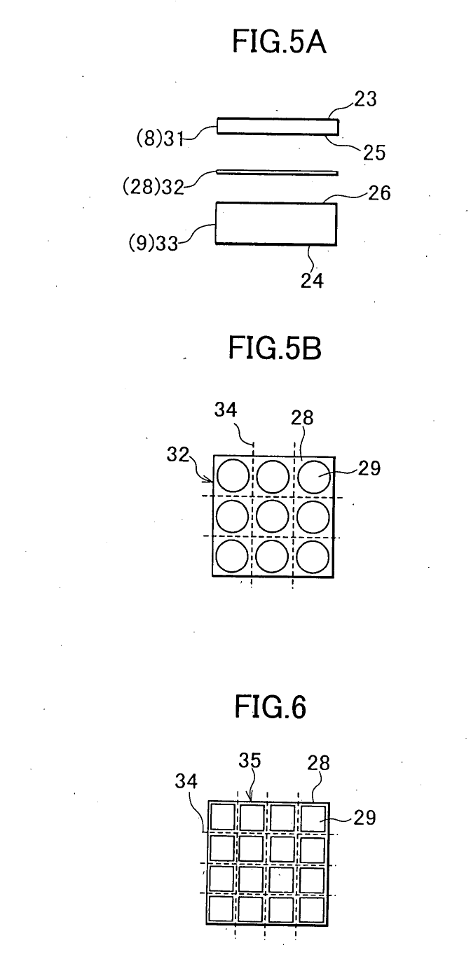

Referring to FIG. 5, description will be given below on a method to manufacture the wavelength conversion optical member 22.

The manufacturing method represents a case where a plurality of wavelength conversion optical members 22 are manufactured in a series of manufacturing process.

A second dielectric reflection film 23 and a dielectric film 25 are formed on a laser crystal plate 31, which is an original plate of the laser crystal 8. A dielectric film 26 and a third dielectric reflection film 24 are formed on a wavelength conversion element plate 33, which is an original plate of the wavelength conversion element 9.

The second dielectric reflection film 23 has such characteristics as being poorly reflective (e.g. reflectivity R<5%) to an excitation light (e.g. 809 nm), and as being highly reflective (e.g. reflectivity R>99.8%) to a fundamental wave (e.g. 1064 nm). The first dielectric reflection film 21 has such characteristics as being non-reflective (e.g. R<0.1%) to the fundamental wave, and as being highly reflective (R>95%) to a secondary higher harmonic wave light (wavelength conversion light; e.g. 532 nm). The third dielectric reflection film 24 has such characteristics as being non-reflective (e.g. reflectivity R<0.1%) to the fundamental wave (e.g. 1064 nm), and as being poorly reflective (e.g. reflectivity R<5%) to the wavelength conversion light (e.g. 532 nm).

The second dielectric reflection film 23 may have such characteristics as being poorly reflective (e.g. reflectivity R<5%) to an excitation light (e.g. 809 nm) and as being non-reflective (e.g. reflectivity R<0.1%) to the fundamental wave (e.g. 1064 nm). The third dielectric reflection film 24 may have such characteristics as being highly reflective (e.g. reflectivity R>99.5%) to the fundamental wave (e.g. 1064 nm) and as being poorly reflective to the wavelength conversion light (e.g. 532 nm).

With the dielectric film 25 and the dielectric film 26 positioned oppositely to each other, a spacer film 32 (i.e. the original film of the spacer 28) is disposed between the dielectric film 25 and the dielectric film 26. The laser crystal plate 31 and the wavelength conversion element plate 33 are cemented together so that crystal axes of the laser crystal plate 31 and the wavelength conversion element plate 33 make a certain predetermined angle.

The laser crystal plate 31, the wavelength conversion element plate 33, and the spacer film 32 are designed in such manner that each of these has a size to be a multiple as required of the size of the wavelength conversion optical member 22. For instance, in FIG. 5, it has in a size for 9 pieces in form of matrix. A circular hole 29 is formed at a portion corresponding to the optical path of each wavelength conversion optical member 22 of the spacer film 32.

The spacer film 32 is placed therebetween, and the laser crystal plate 31 and the wavelength conversion element plate 33 are cemented together. Then, the laser crystal plate 31 and the wavelength conversion element plate 33 are divided to sections, each holding the hole 29, by using cutting lines 34. As a result, a single wavelength conversion optical member 22 as shown in FIG. 2 can be obtained. The hole 29 forms the gap 27.

FIG. 6 shows another form of the spacer film. In a spacer film 35, the hole 29 is in form of a rectangular shape. The hole 29 may be in any shape so far as it does not interfere with the optical path of the laser beam.

According to the method for manufacturing the wavelength conversion optical member 22, the cost, etc. required for the manufacture of the wavelength conversion optical member 22 such as film formation is divided, and this contributes to the reduction of the cost, and a plurality of products with the same quality can be produced.

What is claimed is:

1. A method for manufacturing a wavelength conversion optical member having an optical path portion, comprising:
forming a first dielectric film on a surface of a laser crystal plate having a laser crystal plate crystal axis;
forming a second dielectric film on a surface of a wavelength conversion element plate having a wavelength conversion element plate crystal axis;
aligning said laser crystal plate crystal axis and said wavelength conversion element plate crystal axis so as to have a predetermined angle by arranging a spacer film between said first and second dielectric films, said spacer film having a hole corresponding to said optical path portion; and
cementing said laser crystal plate with said wavelength conversion element plate, wherein one of said dielectric films is poorly reflective to a fundamental wave and highly reflective to a wavelength conversion light, and the other of said dielectric films is poorly reflective to said fundamental wave.

2. The method according to claim 1, wherein said spacer film has a plurality of holes, and wherein said method further comprises dividing said laser crystal plate, said wavelength conversion element plate and said spacer film that are cemented together into a plurality of wavelength conversion optical members so that each of said plurality of wavelength conversion optical members includes one of said plurality of holes.

3. The method according to claim 1, wherein said spacer film is a plated film which is formed on either one of said dielectric films formed on said surface of said laser crystal plate and on said surface of said wavelength conversion element plate.

4. The method according to claim 2, wherein said spacer film is a plated film which is formed on either one of said dielectric films formed on said surface of said laser crystal plate and on said surface of said wavelength conversion element plate.

5. The method according to claim 2, wherein said plurality of holes is arranged in the form of a matrix on said spacer film, and the integrated laser crystal plate and wavelength conversion element plate is divided according to the form of said matrix.

6. The method according to claim 3, wherein said plurality of holes is arranged in the form of a matrix on said spacer film, and the integrated laser crystal plate and wavelength conversion element plate is divided according to the form of said matrix.

7. The method according to claim 4, wherein said plurality of holes is arranged in the form of a matrix on said spacer film, and the integrated laser crystal plate and wavelength conversion element plate is divided according to the form of said matrix.
